(19) United States
(12) Patent Application Publication
(10) Pub. No.: US 2016/0276441 A1
(43) Pub. Date: Sep. 22, 2016

(54) SEMICONDUCTOR DEVICE

(71) Applicant: KABUSHIKI KAISHA TOSHIBA, Tokyo (JP)

(72) Inventor: Masaru FURUKAWA, Himeji Hyogo (JP)

(21) Appl. No.: 14/840,646

(22) Filed: Aug. 31, 2015

(30) Foreign Application Priority Data
Mar. 16, 2015 (JP) 2015-052276

(51) Int. Cl. H01L 29/16; H01L 29/45; H01L 29/872; H01L 29/66; H01L 29/861; H01L 29/868; H01L 29/34; H01L 29/06

(52) U.S. Cl. CPC H01L 29/1608; H01L 29/34; H01L 29/45; H01L 29/0611; H01L 29/6606; H01L 29/8616; H01L 29/868; H01L 29/872

(57) ABSTRACT

A semiconductor device includes an SiC substrate including a first surface and a second surface, the SiC substrate having a first SiC region of a first conductivity type at the first surface, and a second SiC region of a second conductivity type between the first SiC region and the second surface, an insulating film on the first surface around an element region of the semiconductor device and in contact with the first SiC region, a first electrode on the insulating film and comprising a contact electrically connected to the first SiC region, and a second electrode in contact with the second surface. A first conductivity type impurity concentration of the first SiC region that is directly under a center portion of the contact is greater than a first conductivity type impurity concentration of the first SiC region that is directly under a peripheral portion of the contact.

### CROSS-REFERENCE TO RELATED APPLICATION

This application is based upon and claims the benefit of priority from Japanese Patent Application No. 2015-052276, filed Mar. 16, 2015, the entire contents of which are incorporated herein by reference.

### FIELD

Embodiments described herein relate generally to a semiconductor device.

### BACKGROUND

As a factor causing deterioration of the reliability of a semiconductor device, variation in performance caused by an electric charge trapped or lingering in an insulating film is known. For example, the electric charge is trapped by the insulating film during an operation of the semiconductor device, and thus fluctuation of the breakdown voltage or of the leakage current of the semiconductor device occurs.

### DESCRIPTION OF THE DRAWINGS

FIG. 1 is a schematic sectional view of a semiconductor device according to a first embodiment.

FIG. 2 is a schematic plan view of the semiconductor device according to the first embodiment.

FIG. 3 is an enlarged sectional view of a contact portion of the semiconductor device according to the first embodiment.

FIG. 4 is an enlarged sectional view of a contact portion of a semiconductor device of a comparative embodiment.

FIG. 5 is a schematic plan view of a modification example of the first embodiment.

FIG. 6 is a schematic sectional view of the semiconductor device according to a second embodiment.

### DETAILED DESCRIPTION

Embodiments provide a semiconductor device with improved reliability.

In general, according to one embodiment, a semiconductor device includes an SiC substrate including a first surface and a second surface, the SiC substrate having a first SiC region of a first conductivity type at the first surface, and a second SiC region of a second conductivity type between the first SiC region and the second surface. The semiconductor device further includes an insulating film on the first surface around an element region of the semiconductor device and in contact with the first SiC region, a first electrode on the insulating film and comprising a contact electrically connected to the first SiC region, and a second electrode in contact with the second surface. A first conductivity type impurity concentration of the first SiC substrate region that is directly under the center portion of the contact is greater than a first conductivity type impurity concentration of the first SiC region that is directly under a peripheral portion of the contact.

Hereinafter, the description of an embodiment will be given with reference to the drawings. Like reference numerals and letters are given to elements of the drawings and description regarding elements which are described once is omitted where proper.

In addition, in the following description, the indication of n⁺, n, and n⁻, and, p⁺, p, and p⁻ represents the relative impurity concentrations in each conductivity type. That is, n⁺ represents that the n-type impurity concentration is relatively higher than n, and n⁻ represents that the n-type impurity concentration is relatively lower than n. Further, p⁺ represents that the p-type impurity concentration is relatively higher than p, and p⁻ represents that the p-type impurity concentration is relatively lower than p. Meanwhile, there are some cases in which n⁺-type and n⁻-type is simply referred to as the n-type, and p⁺-type and p⁻-type is simply referred to as the p-type.

It is possible to measure the impurity concentration by using, for example, a secondary ion mass spectrometry (SIMS). In addition, the relative low and high for the impurity concentration may be determined by the low and high of the carrier concentration which is obtained by, for example, scanning capacitance microscopy (SCM).

Further, in the present specification, a “SiC substrate” is assumed to include, for example, a SiC layer which is formed on another substrate by epitaxial growth.

### First Embodiment

The semiconductor device according to the embodiment includes an SiC substrate including a first surface and a second surface, an element region which is located in the SiC substrate, an insulating film which is located on the first surface around the element region, a first p-type SiC region which is located in the first surface of the SiC substrate and in contact with the insulating film, an n-type SiC region which is located between the first SiC region and the second surface, a first electrode which is located on the insulating film and includes a contact portion for electrically connecting to the first SiC region, and a second electrode which is located adjacent to the second surface, in which the p-type impurity concentration of the SiC substrate positioned directly under the center portion of the contact portion is higher than the p-type impurity concentration of the SiC substrate positioned directly under the end portion of the contact portion.

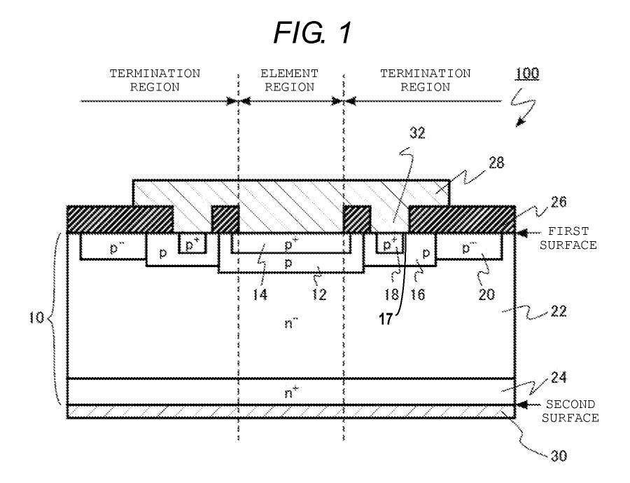

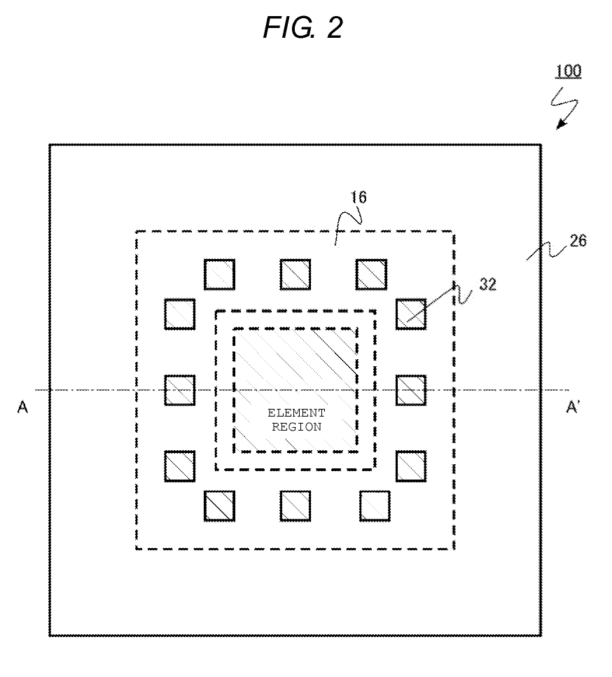

FIG. 1 is a schematic sectional view of the semiconductor device according to the embodiment. FIG. 2 is a schematic plan view of the semiconductor device according to the embodiment. FIG. 2 illustrates a pattern of the insulating film located on a SiC substrate 10. FIG. 1 illustrates a sectional view taken along line A-A′ of FIG. 2. The semiconductor device according to the embodiment is a PIN diode.

A PIN diode 100 is provided with an element region (an active region), and a termination region which surrounds the element region. The element region and the termination region are located in the SiC substrate. The element region functions as a region into which an electric current mainly flows when the PIN diode 100 is forward biased. When the PIN diode 100 is reverse biased, the termination region alleviates the strength of the electric field which is applied to the end portion of the element region, and functions as a region which causes the breakdown voltage of the PIN diode 100 to be improved.

Referring to FIG. 1, the PIN diode 100 is provided using a SiC (silicon carbide) substrate 10, a p-type anode region 12, a p⁺-type anode region 14, a p-type reserve region (a first SiC region) 16, a p⁺-type contact region (a third SiC region) 18, a p⁻-type reserve region (a fourth SiC region) 20, an n⁻-type drift region (a second SiC region) 22, an n⁺-type cathode region 24, a field oxide film (the insulating film) 26, an anode electrode (a first electrode) 28, and a cathode electrode (a second electrode) 30.

The SiC substrate 10 has a first surface and an opposed second surface. In FIG. 1, the first surface corresponds to a surface of the SiC substrate 10 on the upper side in the drawing, and the second surface corresponds to a surface of the SiC substrate 10 on the lower side in the drawing.

The SiC substrate 10 is, for example, a SiC substrate having a 4H-SiC structure. The thickness of the SiC substrate 10 is, for example, 5 μm to 100 μm.

The p-type anode region 12 is located in the element region on or extending inwardly of the first surface of the SiC substrate 10. The p-type anode region 12 includes p-type impurities therein. The p-type impurity is, for example, aluminum (Al). The concentration of the p-type impurity is, for example, in a range of 1×10¹⁸ cm⁻³ to 2×10¹⁹ cm⁻³.

The p⁺-type anode region 14 is located in the element region on or extending inwardly of the first surface of the SiC substrate 10. The p⁺-type anode region 14 extends inwardly of the p-type anode region 12. The p⁺-type anode region 14 contains p-type impurities. The p-type impurity is, for example, aluminum (Al). The concentration of the p-type impurity is, for example, in a range of 3×10¹⁹ cm⁻³ to 1×10²⁰ cm⁻³.

The p-type reserve region (the first SiC region) 16 is located on, or extending inwardly of, the first surface of the SiC substrate 10 and surrounds the element region. The p-type reserve region 16 contains p-type impurities. The p-type impurity is, for example, aluminum (Al).

The p-type impurity concentration of the p-type reserve region 16 is lower than, for example, the p-type impurity concentration of the p-type anode region 12. The concentration of the p-type impurity is, for example, in a range of 5×10¹⁷cm⁻³to 1×10¹⁹cm⁻³. In addition, the p-type reserve region 16 has a depth extending inwardly of the first surface of the SiC substrate 10 which is less than that of the p-type anode region 12. In other words, the thickest portions of the p-type anode region 12 are thicker than the thickest portions of the p-type reserve region 16.

The p⁺-type contact region (the third SiC region) 18 is located within the p-type reserve region 16. The p⁺-type contact region 18 contains p-type impurities. The p-type impurity is, for example, aluminum (Al).

The p-type impurity concentration of the p⁺-type contact region 18 is higher than the p-type impurity concentration of the p-type reserve region 16. The p-type impurity concentration of the p⁺-type contact region 18 is preferably higher by twice or more than that of the p-type impurity concentration of the p-type reserve region 16. The p-type impurity concentration of the p⁺-type contact region 18 is, for example, in a range of 3×10¹⁹ cm⁻³ to 1×10²⁰ cm⁻³.

The p⁻-type reserve region (the fourth SiC region) 20 surrounds the p-type reserve region 16 and is in contact with the p-type reserve region 16. The p⁻-type reserve region 20 contains p-type impurities. The p-type impurity is, for example, aluminum (Al).

The p-type impurity concentration of the p⁻-type reserve region 20 is lower than, for example, the p-type impurity concentration of the p-type reserve region 16. The concentration of the p-type impurity is, for example, in a range of 1×10¹⁷ cm⁻³ to 5×10¹⁸ cm⁻³. In addition, the p⁻-type reserve region 20 has a depth, for example, which is shallower than that of the p-type reserve region 16. In other words, the thickest portion of the p-type reserve region 16 is thicker than the thickness of the p⁻-type reserve region 20.

It is possible to improve the breakdown voltage of the PIN diode 100 by providing the p⁻-type reserve region 20.

The n⁻-type drift region (the second SiC region) 22 is located at least between the p-type reserve region 16 and the p-type anode region 12, and the second surface. The n⁻-type drift region 14 contains n-type impurities. The n-type impurity is, for example, nitrogen (N). The concentration of the n-type impurity is, for example, in a range of 5×10¹⁵ cm⁻³ to 2×10¹⁶ cm⁻³.

The n⁺-type cathode region 24 is located at, and extends inwardly of, the second surface of the SiC substrate 10. The n⁺-type cathode region 24 contains n-type impurities. The n-type impurity is, for example, nitrogen (N). The concentration of the n-type impurity is, for example, in a range of 1×10¹⁹ cm⁻³ to 1×10²¹ cm⁻³.

The field oxide film (the insulating film) 26 is selectively located on the first surface around the element region. The field oxide film 26 is located on portions of the p-type reserve region 16. In other words, portions of the p-type reserve region 16 are located at the first surface in the SiC substrate 10 so as to be in contact with the field oxide film 26.

The field oxide film 26 includes an opening portion therethrough at the element region. In addition, the field oxide film 26 includes an opening portion (a contact hole) extending therethrough at the p-type reserve region 16. The field oxide film 26 is, for example, a silicon oxide film. The thickness of the field oxide film 26 is, for example, in a range of 0.2 μm to 0.6 μm.

The anode electrode (the first electrode) 28 is located on the field oxide film 26. The anode electrode 28 includes a portion which is electrically connected to the p⁺-type anode region 14 through the opening through the oxide film 26 at the element region. It is preferable that the contact between the anode electrode 28 and the p⁺-type anode region 14 is an ohmic contact.

A portion of the anode electrode 28 also extends as a contact 32 which is electrically connected to the p-type reserve region 16. The contact 32 is the portion of the anode electrode 28 which is formed in the opening portion (the contact hole) which extends through the field oxide film 26.

The anode electrode 28 is likewise electrically connected to the p⁺-type contact region 18 by the contact 32. It is preferable that the contact between the contact 32 and the p⁺-type contact region 18 is an ohmic contact. In addition, a peripheral portion 17 of the contact 32 is in direct contact with the p-type reserve region 16.

The contact 32 is provided so as to fix the potential of the p-type reserve region 16 in the termination region to a desired potential. In addition, when a breakdown of the junction is generated in the termination region, the contact 32 is located so as to draw out the electric charge, for example a hole, toward the anode electrode 28.

The size of the contact portion 32 is, for example, in a range of 10 μm×10 μm. The p-type impurity concentration of the SiC substrate 10 positioned directly under the center portion of the contact 32 is that of the p⁺-type contact region 18, for example, 3×10¹⁹ cm⁻³ or more.

The anode electrode 28 is made of a metal. The anode electrode 28 is a structure formed by stacking, for example, an aluminum (Al) layer over a titanium (Ti) layer.

The cathode electrode 30 is located in contact with the second surface of the SiC substrate 10. The cathode electrode 30 is thus in contact with the n⁺-type cathode region 24. It is preferable that the contact of the cathode electrode 30 and the n⁺-type cathode region 24 is an ohmic contact.

The cathode electrode 30 is made of a metal. The cathode electrode 30 is a structure formed by stacking, for example, an aluminum (Al) layer on a titanium (Ti) layer.

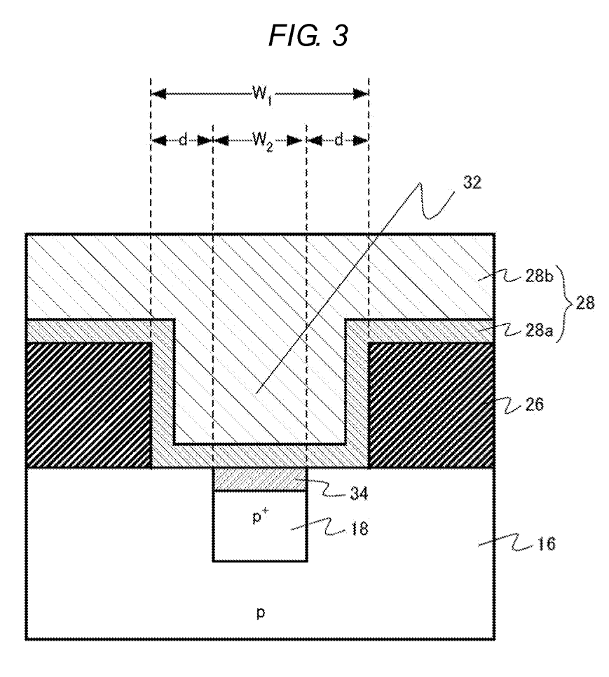

FIG. 3 is an enlarged sectional view of the contact of the semiconductor device according to the embodiment. The anode electrode 28 is a structure formed by stacking a barrier metal layer 28a and a metallic layer 28b. The barrier metal layer 28a is formed of, for example, titanium (Ti). The metallic layer 28b is formed of, for example, aluminum (Al).

A silicide layer 34 is located between at least portions of the contact 32 and the SiC substrate 10. The silicide layer 34 is located between the contact portion 32 and the p⁺-type contact region 18.

The silicide layer 34 reduces the contact resistance generated between the anode electrode 28 and the p⁺-type contact region 18. The silicide layer 34 is formed of, for example, nickel silicide (NiSi).

The width of the p⁺-type contact region 18 (“W₂” in FIG. 3) is smaller than the width of the contact 32 (“W₁” in FIG. 3). The width of the contact 32 is the width of the opening portion on the field oxide film 26. In other words, the width of the contact 32 is the width of the portion of the anode electrode 28 which is embedded into the opening portion on the field oxide film 26. In addition, the area of the p⁺-type contact region 18 on the first surface is smaller than the area of the portion of the contact 32 in contact with the SiC substrate 10 (i.e., p-type reserve region 16).

The p-type impurity concentration of the SiC substrate 10 positioned directly under the center portion of the portion 32 is higher than the p-type impurity concentration of the SiC substrate 10 positioned directly under the peripheral portion of the contact 32.

The contact 32 is connected to the p⁺-type contact region 18 in the center portion thereof. In addition, the contact is connected to the p-type reserve region 16 in the peripheral portion thereof.

The width of the silicide layer 34 is also smaller than the width of the contact 32.

The p⁺-type contact region 18 is separated from the sides of the contact 32 by a predetermined distance (“d” in FIG. 3). The distance d from the side of the contact 32, i.e. the portion of the contact 32 in contact with the field oxide layer 26, to the p⁺-type contact region 18 is preferably 1 μm or more, and is more preferably 2 μm or more.

Similarly, the silicide layer 34 is also separated from the side of the contact 32 by a predetermined distance.

Next, the action and effect of the PIN diode 100 according to the embodiment will be described.

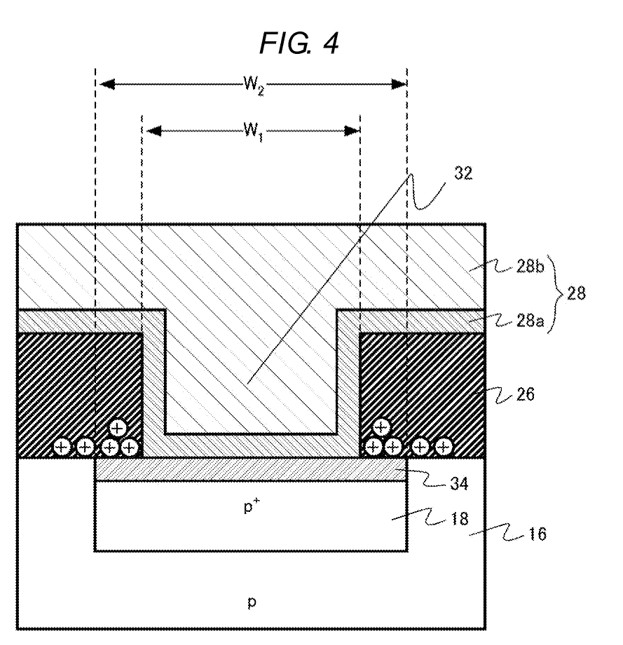

FIG. 4 is an enlarged sectional view of a contact according to a comparative embodiment. In the comparative embodiment, the width of contact region between the p⁺-type region 18 (“W₂” in FIG. 3) is greater than the width of the contact 32 (“W₁” in FIG. 3). In other words, the p-type impurity concentration of the SiC substrate 10 positioned directly under the center portion of the contact 32 is substantially the same as the p-type impurity concentration of the SiC substrate 10 positioned directly under the peripheral region of the contact 32.

When the breakdown of the junction occurs in the termination region, a large current flows into the contact 32. At this time, as illustrated in FIG. 4, holes (the electric charge) become trapped in the field oxide film 26 in the vicinity of the portion 32 or at the adjacent interface between the SiC substrate 10 and the field oxide film 26.

By trapping the holes in the field oxide film 26, the charge balance in the termination region collapses, i.e., becomes imbalanced. When the charge balance in the termination region collapses, a breakdown voltage fluctuation in the termination region is generated. Therefore, the breakdown voltage of the PIN diode fluctuates based on the size of the imbalance based on the quantity of holes trapped in the field oxide firm.

For example, as compared with a device using Si (silicon) , a device using the compound semiconductor SiC may be formed to have a high breakdown voltage. In the device having the high breakdown voltage, when the breakdown of the junction occurs, the current density or an amount of current flowing through the contact in the termination region will be greater than in a silicon based device. For this reason, a defect in reliability due to the fluctuation of the breakdown voltage caused by the trapped electric field becomes obvious because meaningful differences in breakdown voltage occur.

In the PIN diode 100 according to the embodiment, the width of the p⁺-type contact region 18 is smaller than the width of the contacting area of the contact 32 in contact with both the reserve region 16 and contact region 18 of the SiC substrate 10. With this, the resistance of the SiC substrate positioned under the peripheral portion of the contact 32 (reserve region 16) is higher than the resistance of the SiC substrate positioned under the center portion of the contact 32 (contact portion 18). In addition, the contact resistance between the anode electrode 28 and the SiC substrate 10 at the peripheral portion of the contact 32 (reserve region 16) is higher than the contact resistance between the anode electrode 28 and the SiC substrate 10 at the center portion of the contact 32 (contact portion 18).

For this reason, when the breakdown of the junction occurs in the termination region, the current flowing into the contact 32 concentrates in the vicinity of the center portion of the contact 32, and thus the amount of current flowing in the peripheral portion of the contact 32 is smaller. Accordingly, holes may be prevented from being trapped in the field oxide film 26 or at the interface because the current flowing from the contact is concentrated at a region spaced from the interface of the field oxide film 26 with the contact 32. Therefore, it is possible to prevent, or significantly reduce, breakdown voltage fluctuation in the termination region.

In order to properly suppress the amount of current flowing in the peripheral portion side of the contact 32, the distance d from the side of the contact 32, i.e., where the side wall of the contact contacts the field oxide layer 26 directly adjacent to the first surface, to the p⁺-type contact region 18 is preferably 1 μm or more, and is more preferably 2 μm or more.

In order to properly suppress the amount of current flowing in the peripheral portion of the contact 32, the p-type impurity concentration of the p⁺-type contact region 18 is preferably at least twice as great as that of the p-type impurity concentration of the p-type reserve region 16. In other words, the p-type impurity concentration of the SiC substrate 10 positioned directly under the center portion of the contact portion 32 is preferably higher than that of the p-type impurity concentration of the SiC substrate 10 positioned directly under the peripheral portion of the contact portion 32.

In the embodiment, the silicide layer 34 which reduces the contact resistance is located between the anode electrode 28 (contact 32) and the p⁺-type contact region 18. The width of the silicide layer 34 is smaller than the width of the contact 32, and thus a difference between the contact resistance of the peripheral portion of the contact 32 and the contact resistance of the center portion of the contact 32 is increased. Accordingly, the amount of current flowing in the peripheral portion of the contact 32 is further suppressed.

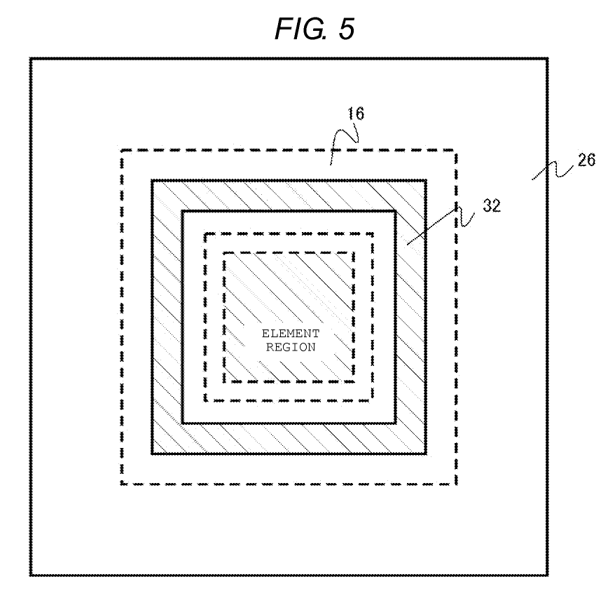

FIG. 5 is a schematic plan view of a modification example of the embodiment. FIG. 5 illustrates a pattern of the insulating film located directly on the SiC substrate 10. The contact 32 may be formed into a shape surrounding the element region as illustrated in FIG. 5, such as rectangular as shown, or other shapes which surround the element region.

In the embodiment, the case in which the p-type reserve region 16 has an impurity concentration and a depth different from those of the p-type anode region 12 is described as an example; however, the p-type reserve region 16 and the p-type anode region 12 may have the same impurity concentration and depth as each other. For example, the p-type reserve region 16 and the p-type anode region 12 may be an impurity region formed by the same process, i.e., in the same process step.

Nonetheless, in the embodiment, by preventing the electric charge from being trapped in the field oxide film 26 in the termination region, the fluctuation of the breakdown voltage is suppressed and thus a PIN diode 100 having improved reliability is achieved.

### Second Embodiment

The configuration of the semiconductor device according to the embodiment is the same as that in the first embodiment except that a Schottky barrier diode (SBD) is employed instead of the PIN diode. Therefore, some of the same description as that in the first embodiment will not be repeated.

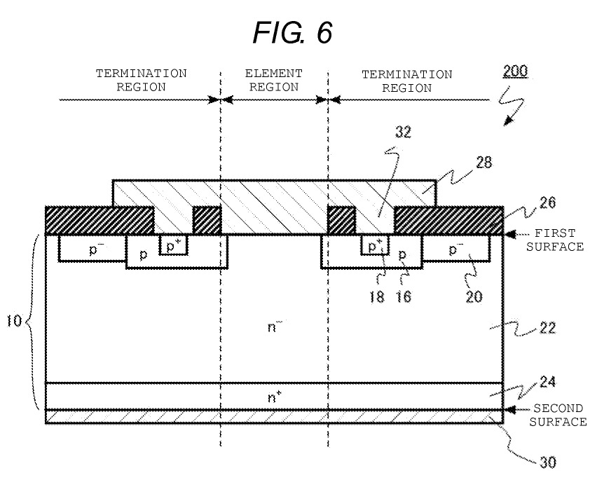

FIG. 6 is a schematic sectional view of the semiconductor device according to the embodiment. The semiconductor device according to the embodiment is the Schottky barrier diode (SBD).

An SBD 200 is provided with an element region and a termination region surrounding the element region. The element region functions as a region in which electric current mainly flows when the SBD 200 is forwardly biased. When the SBD 200 is reverse biased, the termination region alleviates the electric field strength which is applied to the side portions of the element region, and functions to cause the element breakdown voltage of the SBD 200 to be improved.

The SBD 200 is provided on or in an SiC substrate 10, and includes a p-type reserve region (a first SiC region) 16, a p⁺-type contact region (a third SiC region) 18, a p⁻-type reserve region (a fourth SiC region) 20, an n⁻-type drift region (a second SiC region) 22, an n⁺-type cathode region 24, a field oxide film (an insulating film) 26, an anode electrode (a first electrode) 28, and a cathode electrode (a second electrode) 30.

The field oxide film 26 includes an opening portion therethrough in the element region. In addition, the field oxide film 26 includes an opening therethrough in the p-type reserve region 16.

The anode electrode 28 is located on the field oxide film 26. The anode electrode 28 is electrically connected to the n⁻-type drift region 22 through the opening thereof in the element region. It is preferable that the contact between the anode electrode 28 and the n⁻-type drift region 22 is a Schottky contact.

The anode electrode 28 includes a contact 32 extending therefrom into electrical connection with the p-type reserve region 16. In addition, the anode electrode 28 is electrically connected to the p⁺-type contact region 18 by the contact 32.

A structure of the contact 32 of the SBD 200 is the same as that in the first embodiment.

According to the embodiment, by preventing an electric charge from being trapped in the field oxide film 26 in the termination region, the fluctuation of the breakdown voltage is suppressed and thus an SBD 200 having improved reliability may be achieved.

As described above, in the embodiment, the case of 4H-SiC is exemplified as a crystal structure of SiC; however, the exemplary embodiment is applicable to a device using another crystal structure of SiC such as 6H-SiC or 3C-SiC.

In addition, in the embodiment, the examples of the PIN diode and SBD have been described; however, as long as a device is configured with a termination region around the element region, the exemplary embodiment is applicable to other devices such as a metal insulator semiconductor field effect transistor (MISFET), and an insulated gate bipolar transistor (IGBT).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
an SiC substrate including a first surface and a second surface, the SiC substrate having a first SiC region of a first conductivity type at the first surface, and a second SiC region of a second conductivity type between the first SiC region and the second surface;
an insulating film on the first surface around an element region of the semiconductor device and in contact with the first SiC region;
a first electrode on the insulating film and comprising a contact electrically connected to the first SiC region; and
a second electrode in contact with the second surface,
wherein a first conductivity type impurity concentration of the first SiC region that is directly under the center portion of the contact is greater than a first conductivity type impurity concentration of the first SiC region that is directly under a peripheral portion of the contact.

2. The device according to claim 1, further comprising:
a third SiC region of the first conductivity type positioned right under the center portion of the contact portion, the third SiC region having a first conductivity type impurity concentration greater than a first conductivity type impurity concentration of the first SiC region and has a width smaller than a width of the contact.

3. The device according to claim 2,
wherein a distance between a peripheral portion of the contact and the third SiC region is 1 μm or more.

4. The device according to claim. 1, further comprising:
a third SiC region of the first conductivity type around the first SiC region and in contact with the first SiC region, the third SiC region having a first conductivity type impurity concentration less than the first conductivity type impurity concentration of the first SiC region.

5. The device according to claim 1, further comprising:
a silicide layer between the contact and the SiC substrate.

6. The device according to claim 5, wherein the silicide layer is between the contact and a first portion of the first SiC region positioned directly under the center portion of the contact, and at least a second portion of the first SiC region and the peripheral portion of the contact are in direct contact.

7. The device according to claim 5,
wherein a width of the silicide layer is smaller than the width of a portion of the contact that is in direct contact with the first SiC region.

8. The device according to claim 1,
wherein the first conductivity type impurity concentration of the first SiC region that is directly under the center portion of the contact is at least twice as large as the first conductivity type impurity concentration of the first SiC region that is directly under the peripheral portion of the contact.

9. The device according to claim 1,
wherein the first conductivity type impurity concentration of the first SiC region that is directly under the center portion of the contact is 3×10¹⁹ cm⁻³ or more.

10. The device according to claim 1,
wherein the insulating film is a silicon oxide film.

11. A semiconductor device, comprising:
a compound semiconductor substrate having a first surface, a second surface, and a first region of a first conductivity type between the first and second surfaces;
a second region of a second conductivity type including a first portion having a first dopant concentration and extending inwardly of the first surface and a second portion that is around the first portion and between the first portion of the second region and the first region, the second portion of the second region having a lower second conductivity type impurity concentration than the first portion of the second region;
a third region of the second conductivity type extending inwardly of the first surface and around the second region, the third region having a first portion extending inwardly of the first surface and a second portion that is around the first portion and between the first portion of the third region and the first region, the second portion of the third region having a lower second conductivity type impurity concentration than the first portion of the third region;
an insulating layer extending over the first surface and including a first opening therethrough overlying the second region and a second opening therethrough overlying the third region; and
a first electrode extending over the insulating layer and contacting the first portion of the second region through the first opening and the first portion of the third region through the second opening,
wherein a central portion of the first electrode extending through the second opening contacts the first portion of the third region, and a peripheral portion of the first electrode extending through the second opening contacts the first portion of the third region.

12. The semiconductor device of claim 11, further comprising a second electrode in contact with the first region,

13. The semiconductor device of claim 11, wherein a distance between the peripheral portion of the first electrode extending through the second opening and the first portion of the third region is 1 μm or more.

14. The semiconductor device of claim 11, further comprising a silicide layer between the first electrode and the first portion of the third region.

15. The semiconductor device of claim 11, wherein the second portion of the third region extends around, and contacts, the second portion of the second region, and has at least one region that is surrounded by the first portion of the third region.

16. The semiconductor device of claim 11, wherein a first conductivity type impurity concentration of the first portion of the second region is at least twice a first conductivity type impurity concentration of the second portion of the second region.

17. The semiconductor device of claim 11, wherein the compound semiconductor comprises silicon carbide.

18. A method of reducing charge accumulation in an insulating layer adjacent to a contact extending through an opening in an insulating layer from an electrode to a termination region of a semiconductor device formed with a silicon carbide substrate, comprising;
providing a first region of a first conductivity type that extends inwardly of a substrate surface; and
providing a second region of the first conductivity type region that extends inwardly of the substrate surface, the second region surrounding the first region and having a lower first conductivity type impurity concentration than the first region,
wherein the first and second regions are directly under the contact, and the first region is spaced apart from an inner wall of the insulating layer exposed by the opening.

19. The method of claim 18, further comprising:
providing a third region of the first conductivity type surrounding the second region, the third region having a lower first conductivity type impurity concentration than the second region.

20. The method of claim 19, wherein the second region extends inwardly of the substrate surface further than the third region.
